(19) United States
(12) Patent Application Publication
(10) Pub. No.: US 2023/0353125 A1
(43) Pub. Date: Nov. 2, 2023

(54) SWITCH-BASED VARIABLE ACOUSTIC RESONATOR

(71) Applicant: Avago Technologies International Sales Pte. Limited, Singapore (SG)

(72) Inventors: Hongya Xu, Taufkirchen (DE); Martin Handtmann, Riemerling (DE); Lueder Elbrecht, Munchen (DE)

(21) Appl. No.: 17/855,352

(22) Filed: Jun. 30, 2022

Related U.S. Application Data
(60) Provisional application No. 63/336,890, filed on Apr. 29, 2022.

(51) Int. Cl. H03H 9/54; H03H 9/15

(52) U.S. Cl. CPC H03H 9/542; H03H 9/15

(57) ABSTRACT

A resonator may include a first terminal, a second terminal, a resonator between the first terminal and the second terminal, and a reactive element in series with a switch. The reactive element in series with the switch may be connected in parallel with the resonator. The resonator may provide a first set of resonance frequencies when the switch is operated in a non-conducting state and a second set of resonance frequencies when the switch is operated in a conducting state.

### CROSS-REFERENCE TO RELATED APPLICATION

The present application claims the benefit under 35 U.S.C. § 119(e) of U.S. Provisional Application Ser. No. 63/336,890 filed Apr. 29, 2022, entitled SWITCH-BASED VARIABLE ACOUSTIC RESONATOR, naming Hongya Xu, Martin Handtmann, and Lueder Elbrecht as inventors, which is incorporated herein by reference in the entirety.

### TECHNICAL FIELD

The present disclosure relates generally to resonators and, more particularly, to switchable resonators.

### BACKGROUND

Frequency bands for mobile communications standards vary in different regions of the world. As a result, mobile communication devices typically include various front-end filters to allow communication in different frequency bands to support operation in multiple regions of the world. However, supporting many different frequency bands suitable for global compatibility may require many front-end filters, which may undesirably increase cost, weight, and complexity. There is therefore a need to develop systems and methods to cure the above deficiencies.

### SUMMARY

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, explain the principles of the invention.

### BRIEF DESCRIPTION OF DRAWINGS

The numerous advantages of the disclosure may be better understood by those skilled in the art by reference to the accompanying figures.

FIG. 1A is a conceptual schematic of a switchable acoustic resonator including an acoustic resonator connected in parallel with a reactive element, along with a switch in series with the reactive element, in accordance with one or more embodiments of the present disclosure.

FIG. 1B is a conceptual schematic of a parallel-type switchable acoustic resonator formed with a capacitor, in accordance with one or more embodiments of the present disclosure.

FIG. 1C is a conceptual schematic of a parallel-type switchable acoustic resonator formed with an inductor, in accordance with one or more embodiments of the present disclosure.

FIG. 1D is a conceptual schematic of a switchable acoustic resonator including an acoustic resonator connected in series with a reactive element, where the reactive element is connected in parallel with a switch, in accordance with one or more embodiments of the present disclosure.

FIG. 1E is a conceptual schematic of a serial-type switchable acoustic resonator formed with a capacitor, in accordance with one or more embodiments of the present disclosure.

FIG. 1F is a conceptual schematic of a serial-type switchable acoustic resonator formed with an inductor, in accordance with one or more embodiments of the present disclosure.

FIG. 2 is a simplified plot of impedance magnitude of an acoustic resonator as a function of frequency, in accordance with one or more embodiments of the present disclosure.

FIG. 3A is a simplified schematic of a tunable filter including two series resonators and one shunt resonator formed as a parallel-type switchable acoustic resonator, in accordance with one or more embodiments of the present disclosure.

FIG. 3B is a simplified schematic of a tunable filter including one series resonator and one shunt resonator formed as a serial-type switchable acoustic resonator, in accordance with one or more embodiments of the present disclosure.

FIG. 3C is a simplified schematic of a tunable filter including one shunt resonator and one series resonator formed as a serial-type switchable acoustic resonator, in accordance with one or more embodiments of the present disclosure.

FIG. 3D is a simplified schematic of a tunable filter including one shunt resonator and one series resonator formed as a parallel-type switchable acoustic resonator, in accordance with one or more embodiments of the present disclosure.

FIG. 4A is a conceptual plot of a frequency response of a bandpass filter with a tunable low-frequency cut-off, in accordance with one or more embodiments of the present disclosure.

FIG. 4B is a simplified schematic of the tunable filter with a shunt resonator formed as a parallel-type switchable acoustic resonator with an inductor and a switch in an open state, in accordance with one or more embodiments of the present disclosure.

FIG. 4C is a simplified schematic of the tunable filter with a shunt resonator formed as a parallel-type switchable acoustic resonator with an inductor and a switch in a closed state, in accordance with one or more embodiments of the present disclosure.

FIG. 4D is a simplified schematic of the tunable filter with a shunt resonator formed as a parallel-type switchable acoustic resonator with a capacitor and a switch in a closed state, in accordance with one or more embodiments of the present disclosure.

FIG. 4E is a simplified schematic of the tunable filter with a shunt resonator formed as a parallel-type switchable acoustic resonator with a capacitor and a switch in an open state, in accordance with one or more embodiments of the present disclosure.

FIG. 5A is a conceptual plot of a frequency response of a bandpass filter with a tunable low-frequency cut-off, in accordance with one or more embodiments of the present disclosure.

FIG. 5B is a simplified schematic of the tunable filter with a shunt resonator formed as a serial-type switchable acoustic resonator with an inductor and a switch in an open state, in accordance with one or more embodiments of the present disclosure.

FIG. 5C is a simplified schematic of the tunable filter with a shunt resonator formed as a serial-type switchable acoustic resonator with an inductor and a switch in a closed state, in accordance with one or more embodiments of the present disclosure.

FIG. 5D is a simplified schematic of the tunable filter with a shunt resonator formed as a serial-type switchable acoustic resonator with a capacitor and a switch in a closed state, in accordance with one or more embodiments of the present disclosure.

FIG. 5E is a simplified schematic of the tunable filter with a shunt resonator formed as a serial-type switchable acoustic resonator with a capacitor and a switch in an open state, in accordance with one or more embodiments of the present disclosure.

FIG. 6A is a conceptual plot of a frequency response of a bandstop filter with a tunable high-frequency cut-off, in accordance with one or more embodiments of the present disclosure.

FIG. 6B is a simplified schematic of the tunable filter with a shunt resonator formed as a parallel-type switchable acoustic resonator with an inductor and a switch in a conducting state, in accordance with one or more embodiments of the present disclosure.

FIG. 6C is a simplified schematic of the tunable filter with a shunt resonator formed as a parallel-type switchable acoustic resonator with an inductor and a switch in a non-conducting state, in accordance with one or more embodiments of the present disclosure.

FIG. 6D is a simplified schematic of the tunable filter with a shunt resonator formed as a parallel-type switchable acoustic resonator with a capacitor and a switch in a non-conducting state, in accordance with one or more embodiments of the present disclosure.

FIG. 6E is a simplified schematic of the tunable filter with a shunt resonator formed as a parallel-type switchable acoustic resonator with a capacitor and a switch in a conducting state, in accordance with one or more embodiments of the present disclosure.

FIG. 7A is a conceptual plot of a frequency response of a bandstop filter with a tunable high-frequency cut-off, in accordance with one or more embodiments of the present disclosure.

FIG. 7B is a simplified schematic of the tunable filter with a shunt resonator formed as a serial-type switchable acoustic resonator with an inductor and a switch in a conducting state, in accordance with one or more embodiments of the present disclosure.

FIG. 7C is a simplified schematic of the tunable filter with a shunt resonator formed as a serial-type switchable acoustic resonator with an inductor and a switch in a non-conducting state, in accordance with one or more embodiments of the present disclosure.

FIG. 7D is a simplified schematic of the tunable filter with a shunt resonator formed as a serial-type switchable acoustic resonator with a capacitor and a switch in a non-conducting state, in accordance with one or more embodiments of the present disclosure.

FIG. 7E is a simplified schematic of the tunable filter with a shunt resonator formed as a serial-type switchable acoustic resonator with a capacitor and a switch in a conducting state, in accordance with one or more embodiments of the present disclosure.

FIG. 8 is a block diagram depicting a communication device suitable for communication using multiple frequency bands, in accordance with one or more embodiments of the present disclosure.

FIG. 9A is a simplified frequency response plot illustrating selective switching between two partially overlapping frequency bands, in accordance with one or more embodiments of the present disclosure.

FIG. 9B is a simplified frequency response plot illustrating selective switching between two overlapping frequency bands, in accordance with one or more embodiments of the present disclosure.

### DETAILED DESCRIPTION

Reference will now be made in detail to the subject matter disclosed, which is illustrated in the accompanying drawings. The present disclosure has been shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

As used herein, directional terms such as “top,” “bottom,” “over,” “under,” “upper,” “upward,” “lower,” “down,” and “downward” are intended to provide relative positions for purposes of description and are not intended to designate an absolute frame of reference. Various modifications to the described embodiments will be apparent to those with skill in the art, and the general principles defined herein may be applied to other embodiments.

It is to be understood that depicted architectures are merely exemplary and that many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected,” or “coupled,” to each other to achieve the desired functionality, and any two components capable of being so associated can also be viewed as being “couplable,” to each other to achieve the desired functionality. Additionally, unless otherwise indicated, a description indicating that one component is “connected to” another component (alternatively “located on,” “disposed on,” or the like) or “between” components indicates that such components are functionally connected and does not necessarily indicate that such components are physically in contact. Rather, such components may be in physical contact or may alternatively include intervening elements.

Components of a circuit may be connected in various ways. For example, a node may indicate a point of connection between circuit elements or portions thereof. Components connected to a node may be physically connected in any suitable manner. In some embodiments, components connected to a node share a common electrical contact and may thus be, but are not required to be, physically proximate. In some embodiments, components connected to a node are connected through one or more electrically-conductive pathways such as, but not limited to, traces or wires. As another example, a terminal may indicate a portion of a component suitable for connection to one or more additional components and/or external devices. For example, a component may include an input terminal, an output terminal, or any other suitable point of connection. It is to be understood, however, that any descriptions of the connections between circuit components using nodes and/or terminals is solely for illustrative purposes and does not imply any particular technique for connecting such components. Rather, the terms node and terminal are used interchangeably herein.

Embodiments of the present disclosure are directed to systems and methods for switching resonance frequencies of a resonator such as, but not limited to, an acoustic resonator. It is contemplated herein that the properties of a resonator such as, but not limited to, one or more resonance frequencies may be tuned by a reactive element. A reactive element may include any element providing an electrical reactance and may include, but is not limited to, a capacitor or an inductor.

Some embodiments of the present disclosure are directed to a switchable resonator including a resonator (e.g., an acoustic resonator), a reactive element, and a switch to selectively connect the reactive element to the resonator. In this way, switching a state of the switch may modify at least one resonance frequency of the resonator.

A switchable resonator may include any type of resonator known in the art including, but not limited to, a bulk acoustic wave (BAW) resonator or a surface acoustic wave (SAW) resonator. In some embodiments, a switchable resonator includes a film bulk acoustic wave resonator (FBAR), which may also be referred to as a thin film bulk acoustic wave resonator. A switchable resonator may operate at any selected frequency, range of frequencies, or frequency bands. In some embodiments, a switchable resonator is suitable for, but is not limited to, radio frequency (RF) operation in any selected frequency range including, but not limited to, MHz or GHz frequency ranges. In this way, a switchable resonator may be suitable for communication devices such as, but not limited to, cellular communication devices (e.g., at 5G frequency bands, Long Term Evolution (LTE) frequency bands, or the like), Wi-Fi communication devices, or Bluetooth communication devices.

A resonator may exhibit one or more resonance frequencies. For example, resonance frequencies of an acoustic resonator may be related to vibrational frequencies of the constituent materials, which may be related to the physical layout of the resonator. As an illustration, BAW resonators typically include at least two resonance frequencies, which may be referred to as a series resonance frequency and a parallel resonance frequency or alternatively a resonance frequency and an anti-resonance frequency.

It is contemplated herein that an impact of a reactive element coupled to a resonator may depend on the specific design of the resonator and whether the reactive element is in series with or parallel to the resonator.

Continuing the illustration of a BAW resonator, the series resonance frequency and/or the parallel resonance frequency may be tuned through reactive elements in series with or parallel to the resonator. For example, the addition of a capacitor in series with the resonator may increase the series resonance frequency, whereas the addition of a capacitor parallel to the resonator may decrease the parallel resonance frequency. As another example, the addition of an inductor in series with the resonator may decrease the series resonance frequency, whereas the addition of an inductor parallel to the resonator may increase the parallel resonance frequency. Such relationships may be derived for any type or design of resonator including, but not limited to, a SAW resonator or any other type of resonator.

A switchable resonator may include any type of switch known in the art. In some embodiments, a switch includes one or more transistors arranged to operate in a closed state or an open state with respect to an input node and an output node, where an operational state of the switch may be controlled by a drive signal. For example, a switch operating in an open state (e.g., a non-conducting state) may restrict or eliminate current flow between the input node and the output node, whereas a switch operating in a closed state (e.g., a conducting state) may allow current flow between the input node and the output node.

It is contemplated that a switchable resonator as disclosed herein may operate in the same manner as a traditional resonator. In this way, a switchable resonator may be interchangeable with a traditional resonator to provide tunable properties.

Additional embodiments of the present disclosure are directed to a tunable filter including one or more switchable resonators. For example, a filter may typically include one or more resonators, where a frequency response of the filter is based on resonance frequencies of the resonators. As an illustration, a ladder filter may include one or more resonators in series between input and output terminals (e.g., series resonators) and one or more resonators between a ground and nodes connecting the series resistors and/or the input/output terminals (e.g., shunt resonators). In such a configuration, a frequency response of the filter may depend on the selection of the series and parallel resonance frequencies of the series and shunt resonators. For instance, such a filter may have a frequency response of a bandpass filter if the parallel resonance frequency of the series resonators is greater than the series resonance frequency of the shunt resonators. In another instance, such a filter may have a frequency response of a bandstop filter (e.g., a notch filter or a band-reject filter) if the series resonance frequency of the shunt resonators is greater than the parallel resonance frequency of the series resonators.

In some embodiments, a filter includes at least one switchable resonator. In this way, a frequency response of the filter may be tuned by changing one or more resonance frequencies of one or more constituent switchable resonators (e.g., by switching states of switches in the constituent switchable resonators). Continuing the example of a ladder filter above, a filter may include one or more switchable resonators as series resistors and/or shunt resistors. In this way, aspects of the frequency response of the filter including, but not limited to, a low-frequency cut-off, a high-frequency cut-off, or a bandwidth of the filter may be tuned through selective modification of resonance frequencies of the switchable resonators. More generally, a filter as disclosed herein may include exclusively switchable resonators or a combination of switchable resonators and traditional resonators (e.g., non-switchable resonators). Further, a filter as disclosed herein may have any design known in the art and provide any frequency response such as, but not limited to, a low-pass filter, a high-pass filter, a bandpass filter, or a bandstop filter. In this way, modification of resonance frequencies of the constituent switchable resonators may modify any aspect of the frequency response of such a filter such as, but not limited to, a low-frequency cut-off, a high-frequency cut-off, or a bandwidth.

Additional embodiments of the present disclosure are directed to an RF communication system including one or more tunable filters based on resonators and switched reactive elements. For example, a tunable filter including one or more switchable resonators may be, but is not required to be, used as an RF front-end filter (e.g., a passband filter, or the like). Mobile communications systems typically include a set of separate passband filters suitable for operation in each of the passbands supported by the device. It is contemplated herein that a tunable filter including one or more switchable resonators as disclosed herein may be suitable for selective operation in two or more passbands, particularly in applications including partially-overlapping passbands. In this way, the systems and methods disclosed herein may reduce a number of filters (e.g., front-end filters, or the like) necessary to support multi-band communication relative to architectures including separate filters for each passband.

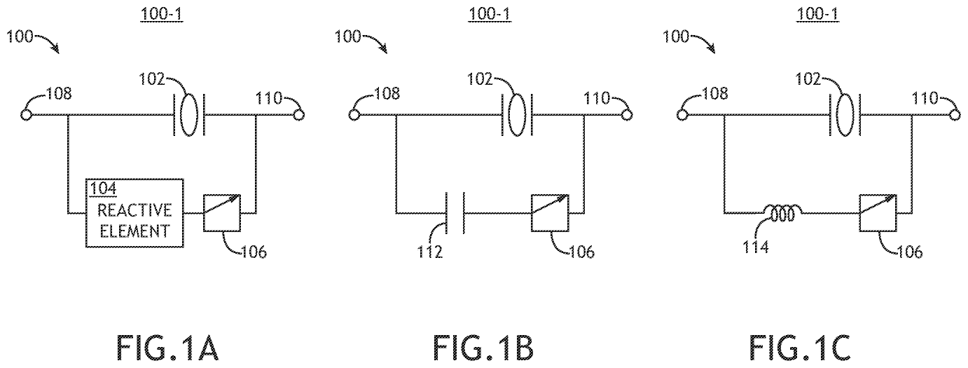

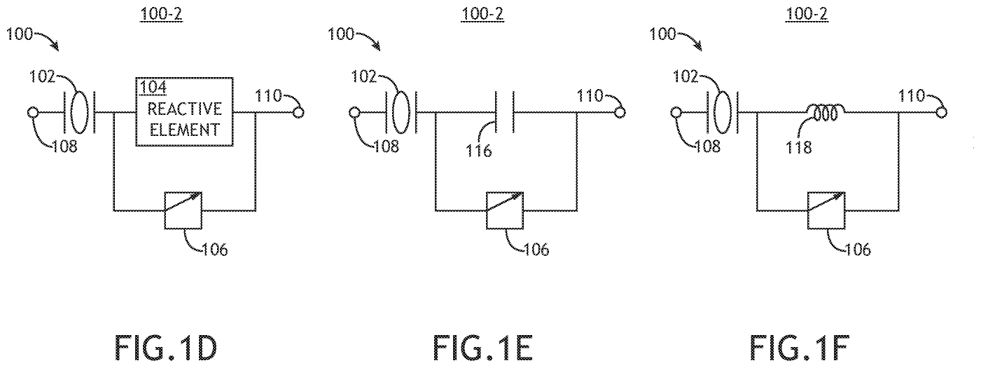

Referring now to FIGS. 1-9B, systems and methods for providing switchable resonators using reactive elements coupled with switches are described in greater detail, in accordance with one or more embodiments of the present disclosure.

In some embodiments, a switchable resonator 100 includes a resonator 102 (e.g., an acoustic resonator) in series or parallel with a reactive element 104, along with a switch 106 to selectively connect the reactive element 104. For example, the switch 106 may selectively connect the reactive element 104 to the resonator 102 in series or parallel (e.g., engage the reactive element 104) and may selectively disconnect the reactive element 104 from the resonator 102 (e.g., disengage the reactive element 104). In this way, operational properties of the switchable resonator 100 such as, but not limited to, resonance frequencies, may be based on the characteristics of the resonator 102 when the reactive element 104 is disconnected, whereas the operational properties of the switchable resonator 100 may be based on the combined characteristics of the resonator 102 and the reactive element 104 when the reactive element 104 is connected. Accordingly, switching a state of the switch 106 may modify at least one resonance frequency of the resonator 102 by selectively connecting or disconnecting the reactive element 104.

A switchable resonator 100 may be formed with any reactive element 104 known in the art. The reactive element 104 may include any element or combination of elements providing an electrical reactance and may include, but is not limited to, an inductor, a capacitor, or a combination thereof. For example, an electrical reactance may be associated with a temporary storage and delayed release of energy from an alternating source. Further, this electrical reactance may depend on a frequency of the alternating source. Further, the reactive element 104 may be connected in parallel with or in series with the resonator 102.

FIG. 1A is a conceptual schematic of a switchable resonator 100 including a resonator 102 connected in parallel with a reactive element 104, along with a switch 106 in series with the reactive element 104, in accordance with one or more embodiments of the present disclosure. Such a structure is referred to herein as a parallel-type switchable resonator 100-1. As illustrated in FIG. 1A, a parallel-type switchable resonator 100-1 may include a resonator 102 and a reactive element 104 connected in parallel between an input terminal 108 (e.g., a switchable resonator input terminal) and an output terminal 110 (e.g., a switchable resonator output terminal), along with a switch 106 in series with the reactive element 104. In this way, the switch 106 in an open state (e.g., non-conducting state) may disconnect the reactive element 104 such that operational characteristics of the parallel-type switchable resonator 100-1 (e.g., as measured between the input terminal 108 and the output terminal 110) are based entirely or substantially on the resonator 102. In contrast, operation of the switch 106 in a closed state (e.g., a conducting state) may connect the reactive element 104 such that the operational characteristics of the parallel-type switchable resonator 100-1 are based on a combination of the resonator 102 and the reactive element 104.

FIG. 1B is a conceptual schematic of a parallel-type switchable resonator 100-1 formed with a capacitor 112, in accordance with one or more embodiments of the present disclosure. FIG. 1C is a conceptual schematic of a parallel-type switchable resonator 100-1 formed with an inductor 114, in accordance with one or more embodiments of the present disclosure.

FIG. 1D is a conceptual schematic of a switchable resonator 100 including a resonator 102 connected in series with a reactive element 104, where the reactive element 104 is connected in parallel with a switch 106, in accordance with one or more embodiments of the present disclosure. Such a structure is referred to herein as a serial-type switchable resonator 100-2. In this configuration, operation of the switch 106 in a closed state may short the reactive element 104 (e.g., disconnect the reactive element 104) such that the operational characteristics of the serial-type switchable resonator 100-2 (e.g., as measured between the input terminal 108 and the output terminal 110) may be based entirely or substantially on the resonator 102. In contrast, operation of the switch 106 in an open state may connect the reactive element 104 such that the operational characteristics of the serial-type switchable resonator 100-2 are based on a combination of the resonator 102 and the reactive element 104.

FIG. 1E is a conceptual schematic of a serial-type switchable resonator 100-2 formed with a capacitor 116, in accordance with one or more embodiments of the present disclosure. FIG. 1F is a conceptual schematic of a serial-type switchable resonator 100-2 formed with an inductor 118, in accordance with one or more embodiments of the present disclosure.

A switchable resonator 100 may include any type of resonator 102 known in the art. In some embodiments, the resonator 102 includes a bulk acoustic wave resonator (BAW) such as, but not limited to, a free-standing BAW device or a solidly-mounted resonator (SMR). For example, the resonator 102 may include a film BAW resonator (FBAR). In some embodiments, the resonator 102 includes a surface acoustic wave (SAW) resonator.

A switchable resonator 100 may further include any type of switch 106 known in the art suitable for selectively connecting the reactive element 104. In some embodiments, the switch 106 includes at least one transistor. For example, the switch 106 may include, but is not limited to, a field-effect transistor (FET), a metal-oxide-semiconductor field-effect transistor (MOSFET), a bipolar junction transistor (BJT), or a heterojunction bipolar transistor (HBT).

Additionally, a switchable resonator 100 may be fabricated using any technique known in the art and on any number of dies. In some applications, the selection of the fabrication technique and/or the number of dies may impact the properties of the switchable resonator 100 as a whole. For example, if the reactive element 104 is a capacitor (e.g., as illustrated in FIGS. 1B or 1E), this capacitor may be integrated on a common die with the switch 106 (e.g., on a complementary metal-oxide-semiconductor (CMOS) die) or on a common die with the resonator 102.

It is further contemplated herein that a switchable resonator 100 may beneficially have minimal or at least acceptable losses. For example, implementing the switch 106 such that it is not in series with the resonator 102 may beneficially provide relatively low losses. As another example in the case of a capacitive reactive element 104, a capacitance value of the capacitor merely adds to a capacitance of the resonator 102 and may therefore not present a parasitic. Rather, the resonator 102 and the capacitive reactive element 104 may be designed together to provide a desired response for both states of the switch 106 (e.g., conducting and non-conducting states).

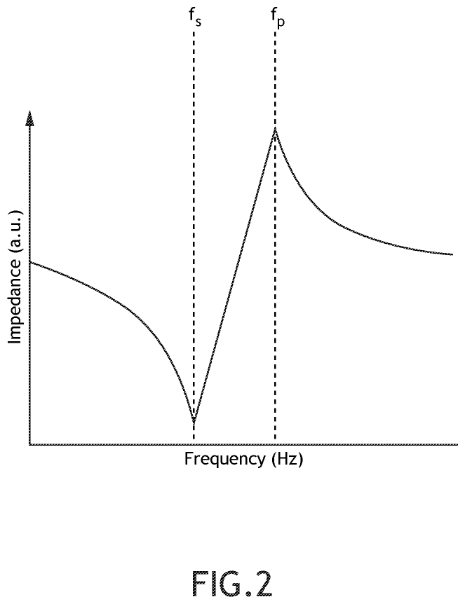

Referring now to FIGS. 2-7E, tuning the operational characteristics of a switchable resonator 100 based on selectively connecting the reactive element 104 is described in greater detail, in accordance with one or more embodiments of the present disclosure.

A resonator 102 may be modeled, at least under certain operating conditions, by an equivalent circuit (e.g., using a Mason approach, a Modified Butterworth-Van Dyke approach, or the like) as a sequence of capacitors, inductors, and resistors that may be characterized by two resonance frequencies. FIG. 2 is a simplified plot of impedance magnitude of a resonator 102 as a function of frequency, in accordance with one or more embodiments of the present disclosure. As illustrated in FIG. 2, a resonator 102 may be characterized by two resonance frequencies, referred to herein as a series resonance frequency (fₛ) associated with an impedance minimum and a parallel resonance frequency (fₚ) associated with an impedance maximum.

It is contemplated herein that selectively connecting a reactive element 104 (e.g., an inductor or a capacitor) either in series with or parallel to the resonator 102 may modify the series resonance frequency and/or the parallel resonance frequency. Referring again to FIGS. 1A-1F, the operational behavior of the switch 106 may depend on the particular configuration or design of the switchable resonator 100.

For example, a switch 106 in a parallel-type switchable resonator 100-1 that is in series with the reactive element 104 may operate to connect the reactive element 104 when in a closed state and disconnect the reactive element 104 when in an open state. Further, connecting a reactive element 104 in parallel to the resonator 102 may typically modify the parallel resonance frequency of the resonator 102. In the case that the reactive element 104 is a capacitor 112 as illustrated in FIG. 1B, connecting this capacitor 112 may decrease the parallel resonance frequency of the resonator 102. In the case that the reactive element 104 is an inductor 114 as illustrated in FIG. 1C, connecting this inductor 114 may increase the parallel resonance frequency of the resonator 102.

As another example, a switch 106 in a serial-type switchable resonator 100-2 that is in parallel with the reactive element 104 may connect the reactive element 104 when in an open state and may disconnect the reactive element 104 when in a closed state. In this configuration, operating the switch 106 in the closed state effectively shorts the reactive element 104. Further, connecting a reactive element 104 in series with the resonator 102 may typically modify the series resonance frequency of the resonator 102. In the case that the reactive element 104 is a capacitor 116 as illustrated in FIG. 1E, connecting this capacitor 116 may increase the series resonance frequency of the resonator 102. In the case that the reactive element 104 is an inductor 118 as illustrated in FIG. 1F, connecting this inductor 118 may decrease the series resonance frequency of the resonator 102.

As a result, both the series resonance frequency and the parallel resonance frequency can be adjusted either higher or lower based on appropriate selection of the type of reactive element 104 and layout (e.g., either a parallel-type switchable resonator 100-1 or a serial-type switchable resonator 100-2).

It is to be understood that FIGS. 1A-1F and the associated descriptions are provided solely for illustrative purposes and are not limiting on the present disclosure. Rather, it is contemplated herein that the present disclosure is not limited to the geometries illustrated in FIGS. 1A-1F. In some embodiments, a switchable resonator 100 includes multiple reactive elements 104 that may be selectively connected by corresponding switches 106. For example, a parallel-type switchable resonator 100-1 may include multiple reactive elements 104 and corresponding switches 106 in separate parallel connections, where the multiple reactive elements 104 may be different in value and/or element type. As an illustration, a parallel-type switchable resonator 100-1 may include a capacitor 112 and an inductor 114 with corresponding switches 106 in separate parallel connections to selectively increase or decrease a value of the parallel resonance frequency. As another illustration, a parallel-type switchable resonator 100-1 may include multiple capacitors or inductors with corresponding switches 106 in separate parallel connections to provide tuning of the parallel resonance frequency by different amounts. Similarly, a serial-type switchable resonator 100-2 may include multiple reactive elements 104 and corresponding switches 106 in separate parallel connections, where the multiple reactive elements 104 may be different in value and/or element type to provide flexible tuning of the magnitude and/or direction of the series resonance frequency. By way of another example, a switchable resonator 100 may include both a reactive element 104 connected in parallel with a resonator 102 and a reactive element 104 connected in series with the same resonator 102, along with corresponding switches 106. In this way, both the series and parallel resonance frequencies of the resonator 102 may be tunable.

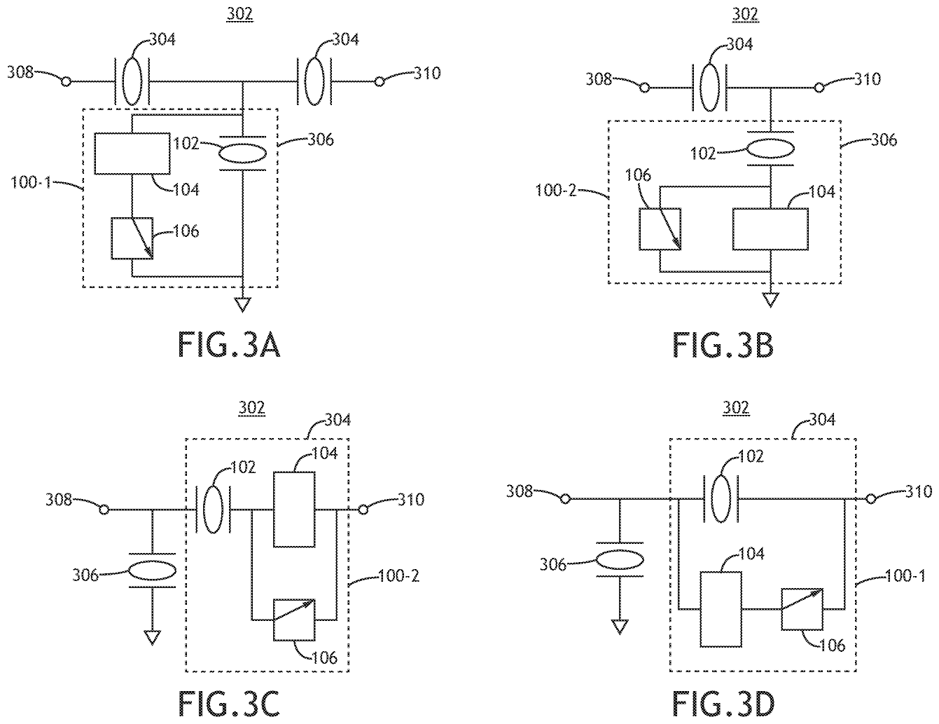

Referring now to FIGS. 3A-7E, tunable filters including one or more switchable resonators 100 are described in greater detail, in accordance with one or more embodiments of the present disclosure.

One or more switchable resonators 100 may be combined to form a tunable filter having any design. In this way, the parallel-type switchable resonator 100-1 illustrated in FIG. 1A and the serial-type switchable resonator 100-2 illustrated in FIG. 1D may be considered tunable building blocks for designing tunable filters. For example, one or more switchable resonators 100 may be combined to form a ladder filter, a lattice filter, or any other filter design. Further, a tunable filter may include any combination of switchable resonators 100 or alternative acoustic resonator designs such as, but not limited to, non-tunable resonators or resonators coupled with variable passive elements. In some embodiments, all resonators in a tunable filter are switchable resonators 100. In some embodiments, a tunable filter includes at least one switchable resonator 100 and at least one alternative resonator design.

It is contemplated herein that any filter design known in the art may be made tunable by replacing one or more traditional acoustic resonators with switchable resonators 100. However, it is to be understood that the present disclosure is not limited to traditional filter designs and that one or more switchable resonators 100 may be incorporated into any filter design.

Further, a tunable filter including one or more switchable resonators 100 may provide any type of frequency response (e.g., filtering response). For the purposes of the present disclosure, the term frequency response is used to refer to the operational characteristics of a filter as a function of a frequency of an input signal (e.g., an input RF signal). For example, operational characteristics of a filter may include, but are not limited to, a cut-off frequency (e.g., a high-frequency cut-off, a low-frequency cut-off, or the like) an amplitude of a passed or blocked signal at any particular frequency, a bandwidth of a filtered band, or a center frequency of a filtered band. As an illustration, a bandpass or a bandstop filter may have a filtered band defined by a low-frequency cut-off and a high-frequency cut-off. For instance, a bandpass filter may pass frequencies between the low-frequency cut-off and the high-frequency cut-off and block other frequencies (e.g., within an operational frequency range), whereas a bandstop filter may block frequencies between the low-frequency cut-off and the high-frequency cut-off and pass other frequencies (e.g., within an operational frequency range). It is noted that cut-off frequencies may generally define a transition point between a passband and a stopband and may be characterized using any suitable metric such as, but not limited to, a frequency at which a signal amplitude changes by 3 dB with respect to a passband. It is further noted that high-pass and low-pass filters may similarly be characterized by a cut-off frequency.

In this way, a switchable resonator 100 may enable selective operation in any of a variety of potential frequency responses based on a selection of operating states of the constituent switches 106 (e.g., selection between open and closed states of the switches 106). In some embodiments, switching a state of a switch 106 of a switchable resonator 100 in a filter modifies the frequency response of the filter by modifying at least one resonance frequency of the associated resonator 102. Further, the states of switches 106 of multiple switchable resonators 100 in a filter may be switched sequentially or simultaneously to modify various aspects of the frequency response of the filter.

In some embodiments, a tunable filter including one or more switchable resonators 100 is formed as a bandpass filter or a bandstop filter (e.g., a notch filter). In this way, various aspects of the filtered band (e.g., a pass band or a rejection band) or the filtering response more generally such as, but not limited to, a low-frequency cut-off, a high-frequency cut-off, a bandwidth, or a center frequency may be tailored by switching states of one or more switches 106 of constituent switchable resonators 100. As an illustration, adjusting a low-frequency cut-off or a high-frequency cut-off may enable selective filtering (e.g., passing or rejecting) of frequencies near the corresponding edges of the filtered band. As another illustration, adjusting both the low-frequency cut-off and the high-frequency cut-off simultaneously may allow for selective control of a bandwidth of the filtered band and/or shifting of a center frequency of the filtered band. In some embodiments, a tunable filter including one or more switchable resonators 100 is formed as a high-pass filter or a low-pass filter. In this way, various aspects of the filtering response (e.g., a cut-off frequency) may be modified by switching states of one or more switches 106 of constituent switchable resonators 100.

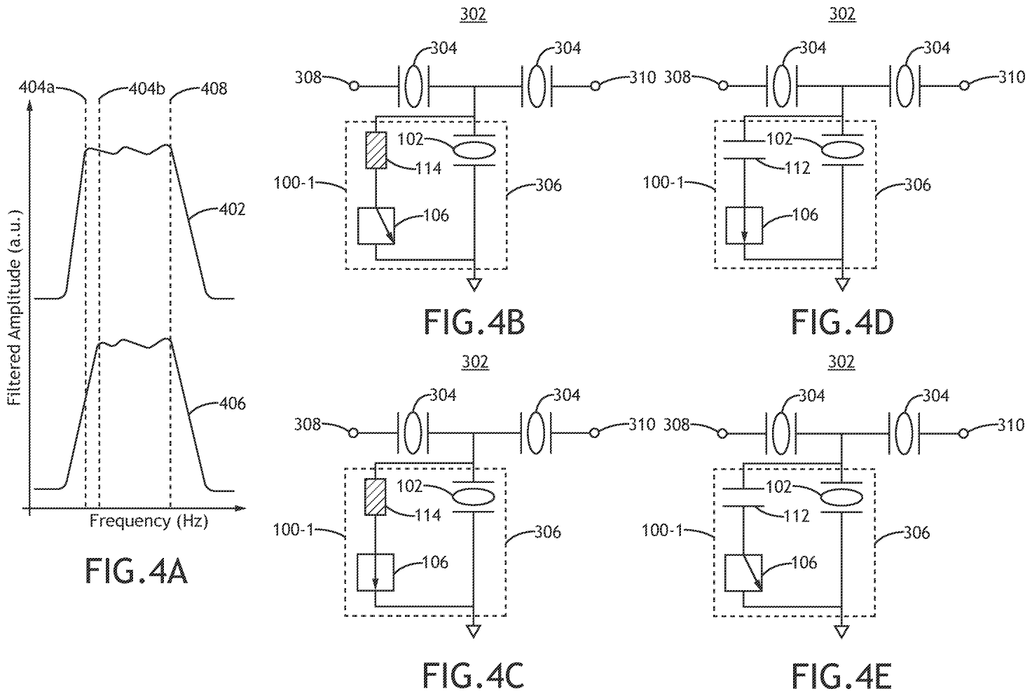

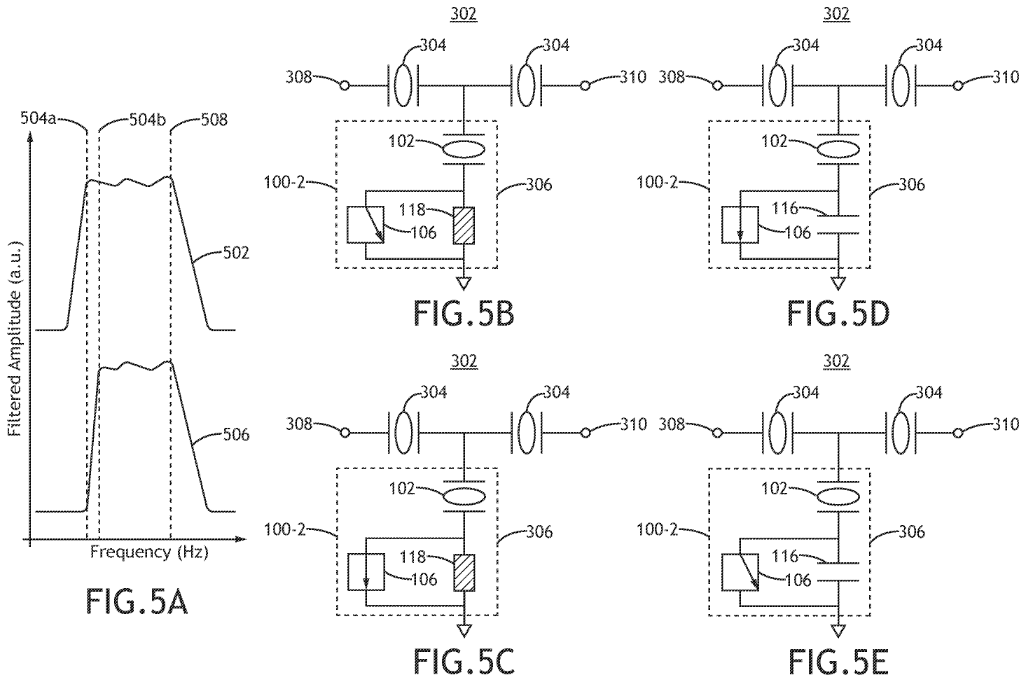

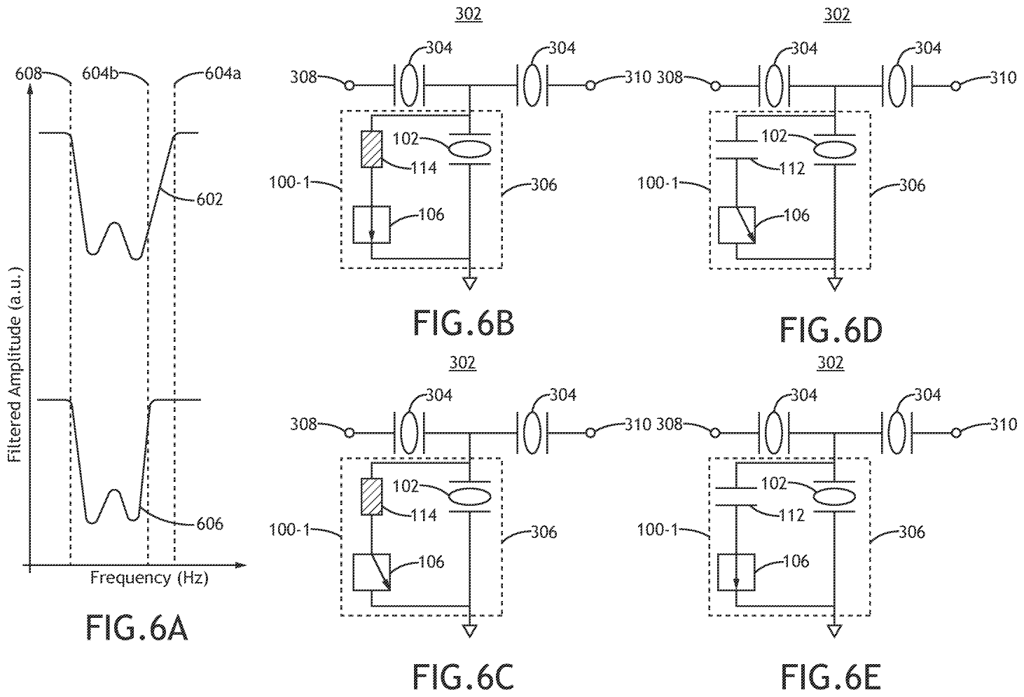

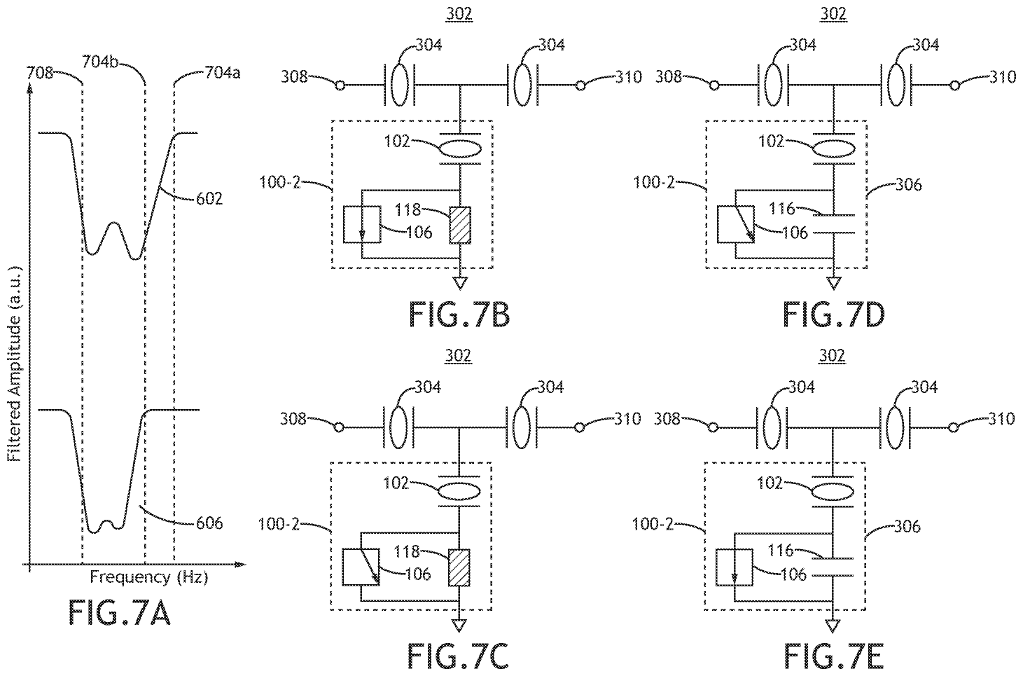

FIGS. 3A-7E illustrate various non-limiting examples of tunable filtering using switchable resonators 100. In particular, FIGS. 3A-3D depict variations of a tunable filter 302 including a switchable resonator 100, FIGS. 4A-5E illustrate the tunable filter 302 configured as a tunable bandpass filter, and FIGS. 6A-7E illustrate the tunable filter 302 configured as a tunable bandstop filter. Further, FIGS. 3A-7E all depict non-limiting illustrations of a ladder filter configuration. For example, a ladder filter may include one or more resonators in series between an input terminal and an output terminal of the filter, which are referred to herein as series resonators. A ladder filter may further include one or more resonators connected between ground and any of the input terminal, the output terminal, or a node between any series resistors. It is contemplated herein that a tunable filter 302 may be formed using one or more switchable resonators 100 as series resonators and/or shunt resonators. However, it is to be understood that the FIGS. 3A-7E and the associated descriptions are provided solely for illustrative purposes and should not be interpreted as limiting.

FIG. 3A is a simplified schematic of a tunable filter 302 including two series resonators 304 and one shunt resonator 306 formed as a parallel-type switchable resonator 100-1, in accordance with one or more embodiments of the present disclosure. FIG. 3B is a simplified schematic of a tunable filter 302 including one series resonator 304 and one shunt resonator 306 formed as a serial-type switchable resonator 100-2, in accordance with one or more embodiments of the present disclosure. FIG. 3C is a simplified schematic of a tunable filter 302 including one shunt resonator 306 and one series resonator 304 formed as a serial-type switchable resonator 100-2, in accordance with one or more embodiments of the present disclosure. FIG. 3D is a simplified schematic of a tunable filter 302 including one shunt resonator 306 and one series resonator 304 formed as a parallel-type switchable resonator 100-1, in accordance with one or more embodiments of the present disclosure. FIGS. 3A-3D further illustrate an input terminal 308 (e.g., a filter input terminal) and an output terminal 310 (e.g., a filter output terminal) for each of the architectures.

As illustrated in FIGS. 3A-3D, a tunable filter 302 may be configured to have any combination of tunable series resonators 304 or shunt resonators 306. Further, any of the architectures of the tunable filter 302 illustrated in FIGS. 3A-3D may be configured to operate as a bandpass filter or a bandstop filter based on the selection of the series resonators 304 and the shunt resonator 306. For example, the tunable filter 302 may operate as a bandpass filter by selecting the parallel resonance frequency of the series resonators 304 to be greater than the series resonance frequency of the shunt resonator 306. As another example, the tunable filter 302 may operate as a bandstop filter by selecting the series resonance frequency of the shunt resonator 306 to be greater than the parallel resonance frequency of the series resonators 304. Further, the tunable filter 302 may operate as a standalone filter or as a portion of a larger ladder filter structure.

It is to be understood that FIGS. 3A-3D are provided solely for illustrative purposes and are not limiting on the present disclosure. For example, a tunable filter 302 may include any number of switchable resonators 100 of any type. Further, a tunable filter 302 including one or more switchable resonators 100 may have any architecture including, but not limited to, a ladder architecture with any number of series resonators 304 or shunt resonators 306, a lattice architecture, or a hybrid architecture.

FIG. 4A is a conceptual plot of a frequency response of a bandpass filter with a tunable low-frequency cut-off, in accordance with one or more embodiments of the present disclosure. In particular, FIG. 4A illustrates a first frequency response 402 with a first low-frequency cut-off 404a and a second frequency response 406 with a second low-frequency cut-off 404b. Further, the first frequency response 402 and the second frequency response 406 have the same high-frequency cut-off 408.

FIGS. 4B-4E illustrate two alternatives for switching between the first frequency response 402 and the second frequency response 406 in FIG. 4A using a parallel-type switchable resonator 100-1 as the shunt resonator 306. In this configuration, an increase of the low-frequency cut-off of the tunable filter 302 may generally be provided by increasing a parallel resonance frequency of the shunt resonator 306. When the shunt resonator 306 is a parallel-type switchable resonator 100-1, this may be achieved by either connecting an inductor 114 or disconnecting a capacitor 112.

FIG. 4B is a simplified schematic of the tunable filter 302 with a shunt resonator 306 formed as a parallel-type switchable resonator 100-1 with an inductor 114 and a switch 106 in an open state, in accordance with one or more embodiments of the present disclosure. This configuration provides the first frequency response 402 shown in FIG. 4A and illustrates a disconnected inductor 114. FIG. 4C is a simplified schematic of the tunable filter 302 with a shunt resonator 306 formed as a parallel-type switchable resonator 100-1 with an inductor 114 and a switch 106 in a closed state, in accordance with one or more embodiments of the present disclosure. This configuration provides the second frequency response 406 shown in FIG. 4A and illustrates a connected inductor 114. In this way, FIGS. 4B and 4C illustrate connecting an inductor 114 in parallel with a resonator 102 to selectively increase the parallel resonance frequency of the parallel-type switchable resonator 100-1, which increases the low-frequency cut-off to switch between the first frequency response 402 and the second frequency response 406 shown in FIG. 4A.

FIG. 4D is a simplified schematic of the tunable filter 302 with a shunt resonator 306 formed as a parallel-type switchable resonator 100-1 with a capacitor 112 and a switch 106 in a closed state, in accordance with one or more embodiments of the present disclosure. This configuration provides the first frequency response 402 shown in FIG. 4A. FIG. 4E is a simplified schematic of the tunable filter 302 with a shunt resonator 306 formed as a parallel-type switchable resonator 100-1 with a capacitor 112 and a switch 106 in an open state, in accordance with one or more embodiments of the present disclosure. This configuration provides the second frequency response 406 shown in FIG. 4A. In this way, FIGS. 4D and 4E illustrate disconnecting a capacitor 112 in parallel with a resonator 102 to selectively increase the parallel resonance frequency of the parallel-type switchable resonator 100-1, which increases the low-frequency cut-off to switch between the first frequency response 402 and the second frequency response 406 shown in FIG. 4A.

FIG. 5A is a conceptual plot of a frequency response of a bandpass filter with a tunable low-frequency cut-off, in accordance with one or more embodiments of the present disclosure. In particular, FIG. 5A illustrates a first frequency response 502 with a first low-frequency cut-off 504a and a second frequency response 506 with a second low-frequency cut-off 504b. Further, the first frequency response 502 and the second frequency response 506 have the same high-frequency cut-off 508.

FIGS. 5B-5E illustrate two alternatives for switching between the first frequency response 502 and the second frequency response 506 in FIG. 5A using a serial-type switchable resonator 100-2 as the shunt resonator 306. As described with respect to FIGS. 4A-4E, an increase of the low-frequency cut-off of the tunable filter 302 may generally be provided by increasing a series resonance frequency of the shunt resonator 306. When the shunt resonator 306 is a serial-type switchable resonator 100-2, this may be achieved by either connecting a capacitor 116 or disconnecting an inductor 118.

FIG. 5B is a simplified schematic of the tunable filter 302 with a shunt resonator 306 formed as a serial-type switchable resonator 100-2 with an inductor 118 and a switch 106 in an open state, in accordance with one or more embodiments of the present disclosure. This configuration provides the first frequency response 502 in FIG. 5A and includes a connected inductor 118 since the switch 106 operates as an open circuit or high impedance. FIG. 5C is a simplified schematic of the tunable filter 302 with a shunt resonator 306 formed as a serial-type switchable resonator 100-2 with an inductor 118 and a switch 106 in a closed state, in accordance with one or more embodiments of the present disclosure. This configuration provides the second frequency response 506 in FIG. 5A and includes a disconnected inductor 118 since the switch 106 is shorting the inductor 118. In this way, FIGS. 5B and 5C illustrate disconnecting an inductor 118 in series with a resonator 102 to selectively increase the series resonance frequency of the serial-type switchable resonator 100-2, which increases the low-frequency cut-off to switch between the first frequency response 502 and the second frequency response 506 shown in FIG. 5A.

FIG. 5D is a simplified schematic of the tunable filter 302 with a shunt resonator 306 formed as a serial-type switchable resonator 100-2 with a capacitor 116 and a switch 106 in a closed state, in accordance with one or more embodiments of the present disclosure. This configuration provides the first frequency response 502 in FIG. 5A and includes a disconnected capacitor 116 since the switch 106 is shorting the capacitor 116. FIG. 5E is a simplified schematic of the tunable filter 302 with a shunt resonator 306 formed as a serial-type switchable resonator 100-2 with a capacitor 116 and a switch 106 in an open state, in accordance with one or more embodiments of the present disclosure. This configuration provides the second frequency response 506 in FIG. 5A and includes a connected capacitor 116 since the switch 106 operates as an open circuit or a high impedance. In this way, FIGS. 5D and 5E illustrate connecting a capacitor 116 in series with a resonator 102 to selectively increase the series resonance frequency of the serial-type switchable resonator 100-2, which increases the low-frequency cut-off to switch between the first frequency response 502 and the second frequency response 506 shown in FIG. 5A.

Referring now generally to FIGS. 4A-5E, it is to be understood that FIGS. 4A-5E are provided solely for illustrative purposes and should not be interpreted as limiting. For example, FIGS. 4A-5E illustrate a particular non-limiting technique for tuning a low-frequency cut-off of a bandpass filter. In some embodiments, a tunable filter is configured as a bandpass filter in an architecture similar to FIG. 3A, but with one or more switchable resonators 100 as the series resonators 304, where a switchable resonator 100 as a series resonator 304 may be configured as either a parallel-type switchable resonator 100-1 or a serial-type switchable resonator 100-2. In this way, the one or more switchable resonators 100 as series resonators 304 may selectively tune a high-frequency cut-off of the bandpass filter through selective modification of either the series resonance frequencies or the parallel resonance frequencies of the series resonators 304. In some embodiments, a tunable filter is configured as a bandpass filter in an architecture similar to FIG. 3A, but with one or more switchable resonators 100 as both series resonators 304 and the shunt resonator 306. In this way, any combination of a low-frequency cut-off or a high-frequency cut-off of a filtered band may be selectively modified. Further, as described previously herein, one or more switchable resonators 100 may be utilized in any filter architecture or design such that the depictions of a ladder architecture are merely illustrative and are not limiting.

FIG. 6A is a conceptual plot of a frequency response of a bandstop filter with a tunable high-frequency cut-off, in accordance with one or more embodiments of the present disclosure. In particular, FIG. 6A illustrates a first frequency response 602 with a first high-frequency cut-off 604a and a second frequency response 606 with a second high-frequency cut-off 604b. Further, the first frequency response 602 and the second frequency response 606 have the same low-frequency cut-off 608.

FIGS. 6B-6E illustrate two alternatives for switching between the first frequency response 602 and the second frequency response 606 in FIG. 6A using a parallel-type switchable resonator 100-1 as the shunt resonator 306. In this configuration, a decrease of the high-frequency cut-off of the tunable filter 302 may generally be provided by decreasing a parallel resonance frequency (fₚ) of the shunt resonator 306. When the shunt resonator 306 is a parallel-type switchable resonator 100-1, this may be achieved by either connecting a capacitor 112 or disconnecting an inductor 114.

FIG. 6B is a simplified schematic of the tunable filter 302 with a shunt resonator 306 formed as a parallel-type switchable resonator 100-1 with an inductor 114 and a switch 106 in a closed state, in accordance with one or more embodiments of the present disclosure. This configuration provides the first frequency response 602 in FIG. 6A and illustrates a connected inductor 114. FIG. 6C is a simplified schematic of the tunable filter 302 with a shunt resonator 306 formed as a parallel-type switchable resonator 100-1 with an inductor 114 and a switch 106 in an open state, in accordance with one or more embodiments of the present disclosure. This configuration provides the second frequency response 606 in FIG. 6A and illustrates a disconnected inductor 114. In this way, FIGS. 6B and 6C illustrate disconnecting an inductor 114 in parallel with a resonator 102 to selectively decrease the parallel resonance frequency of the parallel-type switchable resonator 100-1, which decreases the high-frequency cut-off to switch between the first frequency response 602 and the second frequency response 606 shown in FIG. 6A.

FIG. 6D is a simplified schematic of the tunable filter 302 with a shunt resonator 306 formed as a parallel-type switchable resonator 100-1 with a capacitor 112 and a switch 106 in an open state, in accordance with one or more embodiments of the present disclosure. This configuration provides the first frequency response 602 in FIG. 6A and illustrates a disconnected capacitor 112. FIG. 6E is a simplified schematic of the tunable filter 302 with a shunt resonator 306 formed as a parallel-type switchable resonator 100-1 with a capacitor 112 and a switch 106 in a closed state, in accordance with one or more embodiments of the present disclosure. This configuration provides the second frequency response 606 in FIG. 6A and illustrates a connected capacitor 112. In this way, FIGS. 6D and 6E illustrate connecting a capacitor 112 in parallel with a resonator 102 to selectively decrease the parallel resonance frequency of the parallel-type switchable resonator 100-1, which decreases the high-frequency cut-off to switch between the first frequency response 602 and the second frequency response 606 shown in FIG. 6A.

FIG. 7A is a conceptual plot of a frequency response of a bandstop filter with a tunable high-frequency cut-off, in accordance with one or more embodiments of the present disclosure. In particular, FIG. 7A illustrates a first frequency response 702 with a first high-frequency cut-off 704a and a second frequency response 706 with a second high-frequency cut-off 704b. Further, the first frequency response 702 and the second frequency response 706 have the same low-frequency cut-off 708.

FIGS. 7B-7E illustrate two alternatives for switching between the first frequency response 602 and the second frequency response 606 in FIG. 7A using a serial-type switchable resonator 100-2 as the shunt resonator 306. In this configuration, a decrease of the high-frequency cut-off of the tunable filter 302 may generally be provided by decreasing a series resonance frequency of the shunt resonator 306. When the shunt resonator 306 is a serial-type switchable resonator 100-2, this may be achieved by either connecting an inductor 118 or disconnecting a capacitor 116.

FIG. 7B is a simplified schematic of the tunable filter 302 with a shunt resonator 306 formed as a serial-type switchable resonator 100-2 with an inductor 118 and a switch 106 in a conducting state, in accordance with one or more embodiments of the present disclosure. This configuration provides the first frequency response 602 in FIG. 7A and illustrates a disconnected inductor 114 since the switch 106 is shorting the inductor 118. FIG. 7C is a simplified schematic of the tunable filter 302 with a shunt resonator 306 formed as a serial-type switchable resonator 100-2 with an inductor 118 and a switch 106 in an open state, in accordance with one or more embodiments of the present disclosure. This configuration provides the second frequency response 606 in FIG. 7A and illustrates a connected inductor 118 since the switch 106 is operating as an open circuit or a high impedance. In this way, FIGS. 7B and 7C illustrate connecting an inductor 118 in series with a resonator 102 to selectively decrease the parallel resonance frequency of the serial-type switchable resonator 100-2, which decreases the high-frequency cut-off to switch between the first frequency response 602 and the second frequency response 606 shown in FIG. 7A.

FIG. 7D is a simplified schematic of the tunable filter 302 with a shunt resonator 306 formed as a serial-type switchable resonator 100-2 with a capacitor 116 and a switch 106 in an open state, in accordance with one or more embodiments of the present disclosure. This configuration provides the first frequency response 602 in FIG. 7A and illustrates a connected capacitor 116 since the switch 106 is operating as an open circuit or high impedance. FIG. 7E is a simplified schematic of the tunable filter 302 with a shunt resonator 306 formed as a serial-type switchable resonator 100-2 with a capacitor 116 and a switch 106 in a closed state, in accordance with one or more embodiments of the present disclosure. This configuration provides the second frequency response 606 in FIG. 7A and illustrates a disconnected capacitor 116 since the switch 106 is shorting the capacitor 116. In this way, FIGS. 7D and 7E illustrate disconnecting a capacitor 116 in series with a resonator 102 to selectively decrease the parallel resonance frequency of the serial-type switchable resonator 100-2, which decreases the high-frequency cut-off to switch between the first frequency response 602 and the second frequency response 606 shown in FIG. 7A.

Referring now generally to FIGS. 6A-7E, it is to be understood that FIGS. 6A-7E are provided solely for illustrative purposes and should not be interpreted as limiting. For example, FIGS. 6A-7E illustrate a particular non-limiting technique for tuning a high-frequency cut-off of a bandstop filter. In some embodiments, a tunable filter is configured as a bandstop filter in an architecture similar to FIG. 3A, but with one or more switchable resonators 100 as the series resonators 304, where a switchable resonator 100 as a series resonator 304 may be configured as either a parallel-type switchable resonator 100-1 or a serial-type switchable resonator 100-2. In this way, the one or more switchable resonators 100 as series resonators 304 may selectively tune a low-frequency cut-off of the bandstop filter through selective modification of either the series resonance frequencies or the parallel resonance frequencies of the series resonators 304. In some embodiments, a tunable filter is configured as a bandstop filter in an architecture similar to FIG. 3A, but with one or more switchable resonators 100 as both series resonators 304 and the shunt resonator 306. In this way, any combination of a low-frequency cut-off or a high-frequency cut-off of a filtered band may be selectively modified. Further, as described previously herein, one or more switchable resonators 100 may be utilized in any filter architecture or design such that the depictions of a ladder architecture are merely illustrative and are not limiting.

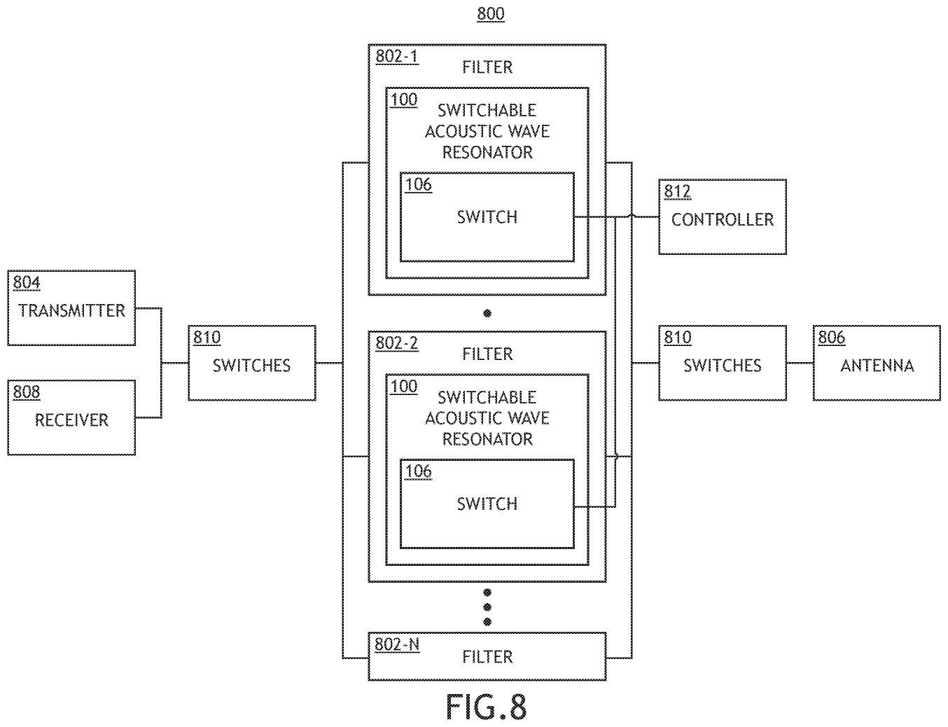

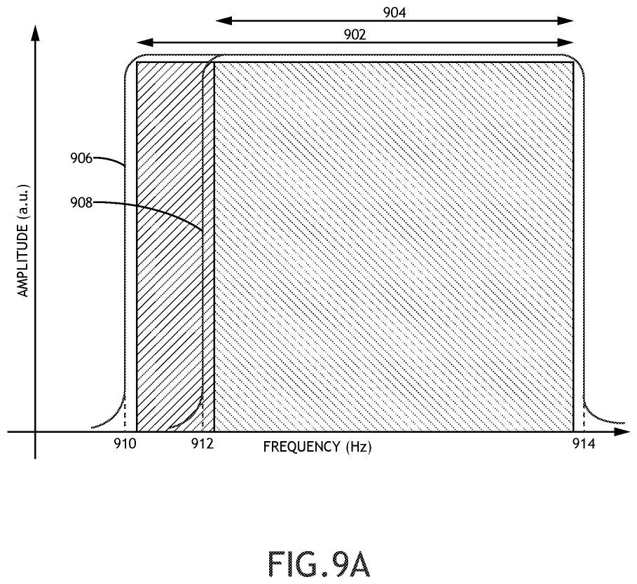

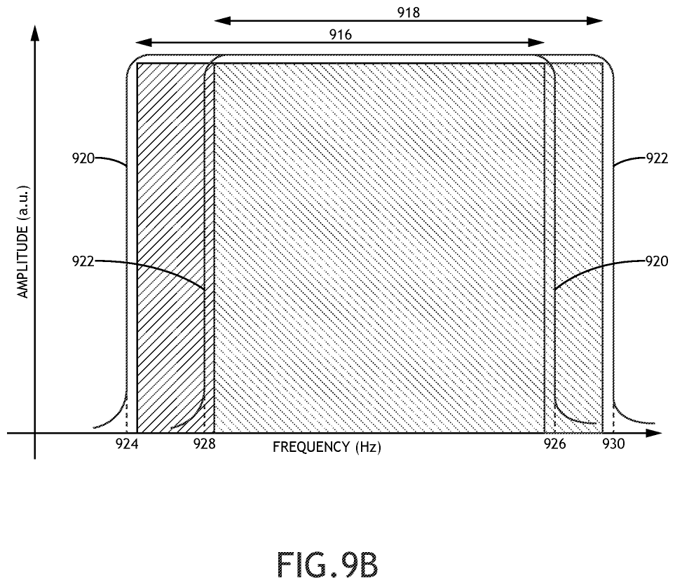

Referring now to FIGS. 8-9B, a communication device 800 including one or more switchable resonators 100 is described in greater detail, in accordance with one or more embodiments of the present disclosure.

FIG. 8 is a block diagram depicting a communication device 800 suitable for communication using multiple frequency bands, in accordance with one or more embodiments of the present disclosure. In some embodiments, a communication device 800 suitable for communication using multiple frequency bands includes one or more filters 802, which may be used for transmitting and/or receiving operations. In FIG. 8, the filters 802 are labeled with reference numbers 802-1 to 802-N to signify N filters 802, where N may be any integer equal to or greater than one. For example, the communication device 800 may include one or more filters 802 between a transmitter 804 and an antenna 806 to provide a signal to be transmitted (e.g., a transmission signal) within one or more selected frequency bands. As another example, the communication device 800 includes one or more filters 802 between the antenna 806 and a receiver 808 to isolate a portion of a received signal within one or more selected frequency bands. The communication device 800 may further include various switches 810 for routing either transmission signals or received signals to or from selected filters 802.

A communication device 800 may incorporate any number of filters 802 in any design. In some embodiments, the communication device 800 includes separate sets of filters 802 for transmitting and receiving operations. In some embodiments, at least some filters 802 are used for both transmitting and receiving operations.

In some embodiments, at least one of the one or more filters 802 is a tunable filter 802 that includes one or more switchable resonators 100 as disclosed herein. Such a tunable filter 802 may have any suitable architecture including, but not limited to, the architecture depicted in FIG. 3A, a ladder architecture of any design, or a lattice architecture of any design. Further, a particular filter 802 may include any combination of a parallel-type switchable resonator 100-1 or a serial-type switchable resonator 100-2.

The filters 802 in a communication device 800 may include any combination of tunable filters 802 including one or more switchable resonators 100 as disclosed herein, tunable filters 802 based on alternative techniques, or non-tunable filters (e.g., static filters). As an illustration, FIG. 8 depicts a non-limiting configuration in which filter 802-1 and filter 802-2 are tunable based on switchable resonators 100 as disclosed herein, whereas filter 802-N is not tunable.

In some embodiments, the communication device 800 includes a controller 812 connected to the constituent switches 106 within tunable filters 802. In this way, the controller 812 may selectively connect or disconnect reactive elements 104 within switchable resonators 100 in any of the tunable filters 802 to provide selected frequency responses suitable for operation in selected frequency bands.

The controller may have any architecture suitable for selectively modifying the states of the switches 106 of switchable resonators 100. In some embodiments, the controller includes one or more processors configured to execute program instructions. Further, the program instructions may be stored on a memory device such as, but not limited to, read-only memory (ROM), random-access memory (RAM), or a solid-state drive. For example, the controller may include any type of processing or logic circuitry such as, but not limited to, a microprocessor, an application specific integrated circuit (ASIC), a field programmable gate array (FPGA), or a digital signal processor (DSP).

It is contemplated herein that a communication device 800 with one or more tunable filters 802 formed with switchable resonators 100 may reduce a total number of filters 802 required for operation in a selected number of frequency bands, which may provide numerous benefits including, but not limited to, decreasing a number of components in the communication device 800, decreasing weight, or decreasing production cost.

For example, a particular tunable filter 802 including one or more switchable resonators 100 may selectively provide operation in two or more frequency bands. Such a configuration may be particularly beneficial for, but is not limited to, applications including partially overlapping or adjacent frequency bands.

FIGS. 9A-9B include non-limiting illustrations of selective tuning of a filter 802 to provide operation in different frequency bands.

FIG. 9A is a simplified frequency response plot illustrating selective switching between two partially overlapping frequency bands, in accordance with one or more embodiments of the present disclosure. In particular, FIG. 9A depicts a first frequency band 902 and a second frequency band 904 that may be utilized by a communication device 800. FIG. 9A further depicts a first frequency response 906 and a second frequency response 908 of a tunable filter 802 including one or more switchable resonators 100 suitable for selectively operating in either the first frequency band 902 or the second frequency band 904.

For example, the first frequency band 902 may have a first lower frequency limit 910 and the second frequency band 904 may have a second lower frequency limit 912, but the first frequency band 902 and the second frequency band 904 may share a common upper frequency limit 914. In this case, a tunable filter 802 with one or more switchable resonators 100 may selectively operate with either the first frequency response 906 or the second frequency response 908 based on selectively connecting or disconnecting the constituent reactive elements 104 within the switchable resonators 100. As a non-limiting illustration, selective operation with either the first frequency response 906 or the second frequency response 908 may be achieved with a tunable filter 302 as depicted in FIGS. 4A-5E.

FIG. 9B is a simplified frequency response plot illustrating selective switching between two overlapping frequency bands, in accordance with one or more embodiments of the present disclosure. In particular, FIG. 9B depicts a third frequency band 916 and a fourth frequency band 918 that may be utilized by a communication device 800. FIG. 9B further depicts a third frequency response 920 and a fourth frequency response 922 of a tunable filter 802 including one or more switchable resonators 100 suitable for selectively operating in either the third frequency band 916 or the fourth frequency band 918.

For example, the third frequency band 916 may have a third lower frequency limit 924 and a third upper frequency limit 926, whereas the fourth frequency band 918 may have a fourth lower frequency limit 928 and a fourth upper frequency limit 930. In this case, a tunable filter 802 with one or more switchable resonators 100 may selectively operate with either the first frequency response 906 or the second frequency response 908 based on selectively engaging or disengaging the constituent reactive elements 104 within the switchable resonators 100. For example, selective operation with either the first frequency response 906 or the second frequency response 908 may be achieved with a tunable filter 302 as depicted in FIG. 3A, where both the series resonators 304 and the shunt resonator 306 include switchable resonators 100 and are thus tunable. In this configuration, the tunable shunt resonator 306 including a switchable resonator 100 may provide selection between the third lower frequency limit 924 and the fourth lower frequency limit 928, whereas the tunable series resonators 304 may provide selection between the third upper frequency limit 926 and the fourth upper frequency limit 930.

It is to be understood, however, that FIGS. 8-9B are provided solely for illustrative purposes and are not limiting on the present disclosure. For example, a communication device 800 is not limited to tunable filters 802 based on the architecture depicted in FIG. 3A and may generally include one or more tunable filters 802 having any architecture based on one or more switchable resonators 100.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected” or “coupled” to each other to achieve the desired functionality, and any two components capable of being so associated can also be viewed as being “couplable” to each other to achieve the desired functionality. Specific examples of couplable include but are not limited to physically interactable and/or physically interacting components and/or wirelessly interactable and/or wirelessly interacting components and/or logically interactable and/or logically interacting components.

It is believed that the present disclosure and many of its attendant advantages will be understood by the foregoing description, and it will be apparent that various changes may be made in the form, construction, and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. A device comprising:
a resonator; and
a reactive element in series with a switch, wherein the reactive element includes at least one of a capacitor or an inductor, wherein the reactive element in series with the switch is connected in parallel with the resonator, wherein switching a state of the switch modifies at least one resonance frequency of the resonator.

2. The device of claim 1, wherein the reactive element comprises:
a capacitor.

3. The device of claim 2, wherein the capacitor is formed on a common die with the resonator.

4. The device of claim 2, wherein the capacitor is formed on a common die with the switch.

5. The device of claim 1, wherein the reactive element comprises:
an inductor.

6. The device of claim 1, wherein modifying the at least one resonance frequency of the resonator by switching the state of the switch comprises:
modifying at least one of a series resonance frequency or a parallel resonance frequency by switching the state of the switch.

7. A filter comprising:
one or more resonators, wherein a frequency response of the filter is based on resonance frequencies of the one or more resonators, wherein at least one of the one or more resonators are incorporated into one or more switchable resonators, wherein a particular one of the one or more switchable resonators comprises:
a particular one of the one or more resonators; and
a reactive element in series with a switch, wherein the reactive element includes at least one of a capacitor or an inductor, wherein the reactive element in series with the switch is connected in parallel with the particular one of the one or more resonators, wherein switching a state of the switch modifies the frequency response of the filter by modifying at least one resonance frequency of the particular one of the one or more resonators.

8. The filter of claim 7, wherein the reactive element comprises:
a capacitor.

9. The filter of claim 8, wherein the capacitor is formed on a common die with the resonator.

10. The filter of claim 8, wherein the capacitor is formed on a common die with the switch.

11. The filter of claim 7, wherein the reactive element comprises:
an inductor.

12. The filter of claim 7, wherein the frequency response comprises at least one of a bandpass frequency response or a bandstop frequency response having a high-frequency cut-off or a low-frequency cut-off, wherein switching the state of the switch in the particular switchable resonator modifies at least one of the high-frequency cut-off or the low-frequency cut-off of the frequency response.

13. The filter of claim 7, wherein the one or more resonators are arranged in a ladder filter configuration.

14. The filter of claim 7, wherein an additional one of the one or more switchable resonators comprises:
an additional one of the one or more resonators in series with an additional reactive element, wherein the additional reactive element includes at least one of an additional capacitor or an additional inductor; and
an additional switch in parallel with the additional reactive element, wherein switching a state of the additional switch modifies the frequency response of the filter by modifying at least one resonance frequency of the additional one of the one or more resonators.

15. A filter comprising:
two or more resonators, wherein a frequency response of the filter is based on resonance frequencies of the two or more resonators, wherein the two or more resonators include a first set of resonators connected in series between a first terminal and a second terminal, wherein the two or more resonators include a second set of resonators connected between a ground and at least one of the first terminal, the second terminal, or a node between any of the first set of resonators, wherein at least one of the first set of resonators is incorporated into one or more switchable resonators, wherein a particular one of the one or more switchable resonators comprises:
a particular one of the one or more resonators;
a reactive element including at least one of a capacitor or an inductor; and
a switch configured to selectively connect the reactive element to the particular one of the one or more resonators, wherein switching a state of the switch modifies the frequency response of the filter by modifying at least one resonance frequency of the particular one of the one or more resonators.

16. The filter of claim 15, wherein the switch is in series with the reactive element, wherein the switch in series with the reactive element is connected in parallel with the particular one of the one or more resonators.

17. The filter of claim 15, wherein the reactive element is in series with the particular one of the one or more resonators, wherein the switch is in parallel with the reactive element.

18. The filter of claim 15, wherein at least one of the second set of resonators is incorporated into one or more additional switchable resonators, wherein a particular one of the one or more additional switchable resonators comprises:
an additional one of the one or more resonators;
an additional reactive element including at least one of an additional capacitor or an additional inductor; and
an additional switch configured to selectively connect the reactive element to the additional one of the one or more resonators, wherein switching a state of the additional switch modifies the frequency response of the filter by modifying at least one resonance frequency of the additional one of the one or more resonators.

19. The filter of claim 18, wherein the additional switch is in series with the additional reactive element, wherein the additional switch in series with the additional reactive element is connected in parallel with the additional one of the one or more resonators.

20. The filter of claim 18, wherein the additional reactive element is in series with the additional one of the one or more resonators, wherein the additional switch is in parallel with the additional reactive element.
